(19) United States
(12) Patent Application Publication
(10) Pub. No.: US 2007/0176674 A1
(43) Pub. Date: Aug. 2, 2007

(54) Semiconductor integrated circuit

(75) Inventor: Tomoki Shioda, Ora-gun (JP)

Correspondence Address: OLIFF & BERRIDGE, PLC, P.O. BOX 19928, ALEXANDRIA, VA, 22320, US

(73) Assignee: SANYO ELECTRIC CO., LTD., MORIGUCHI-SHI (JP)

(21) Appl. No.: 11/655,072

(22) Filed: Jan. 19, 2007

(30) Foreign Application Priority Data
Jan. 30, 2006 (JP) 2006-020790

(51) Int. Cl. H03B 1/00

(52) U.S. Cl. 327/559

(57) ABSTRACT

A coupling capacitor for converting the DC level between circuits is incorporated into a semiconductor integrated circuit to reduce the number components. A high-pass filter (34) having a cutoff frequency f_{C} is composed of a coupling capacitor C₁ that cuts off direct current between circuits (22) and (24), and a switched capacitor circuit (28) constituting an equivalent resistor R_{SC}. If the switching frequency f_{SC} or the capacitance C_{SC} charged and discharged by the switched capacitor circuit (28) is set low, the R_{SC} can be increased and the C₁ at the prescribed f_{C} can be reduced proportionately. Accordingly, the high-pass filter (34) having the C₁ can be integrated onto the chip of the IC (20).

### CROSS-REFERENCE TO RELATED APPLICATION

The priority application number JP2006-020790 upon which this patent application is based is hereby incorporated by reference.

### FIELD OF THE INVENTION

The present invention relates to a direct-current-level (DC-level) signal conversion circuit formed on a semiconductor integrated circuit.

In order to mutually connect circuits having different DC levels, a coupling capacitor is commonly inserted in series between the circuits. A DC cutoff circuit comprising this coupling capacitor constitutes a high-pass filter. FIG. 1 is a schematic diagram showing a structure in which two circuits are connected using a conventional DC cutoff circuit. This diagram shows a structure in which signals are transmitted from a circuit 2 to a circuit 6 inside a semiconductor integrated circuit (IC) 4. A coupling capacitor C₁ is inserted in series in a signal line 8. A resistor R₁ is formed on the semiconductor chip of the IC 4. The resistor R₁ is connected between a prescribed reference DC voltage source Vref and an input terminal 10 of the IC 4 to which signals are input. The capacitor C₁ and resistor R₁ constitute a high-pass filter and prevent the passage of low-frequency signal components. As a result, the DC level between the input and output sides can be set to be different, and the DC level of the output side is set to Vref. The cutoff frequency f_{C} of the high-pass filter is expressed by the following equation.

f_{C}=1/(2πR₁C₁) (1)

In order to assure the operation of the high-pass filter in relation to the above, the input terminal to the circuit 6 must be set to higher impedance than R₁, and a buffer circuit 12 is shown as an example of a method of achieving this.

When the transmitted signals are signals in the audible frequency band (20 Hz to 20 kHz), which are relatively low frequencies, the cutoff frequency f_{C} is set to be lower than 20 Hz, which is the lower limit of the audio band.

When the cutoff frequency f_{C} is 20 Hz and the input impedance R₁ of the input terminal 10 of the IC 4 is 50 kΩ, for example, C₁ in EQ. 1 will be 0.16 μF. C₁ having such a large capacitance will occupy a greater surface area on the IC, and is therefore difficult to be incorporated into the IC 4. Conversely, f_{C} can be reduced if R₁ is increased, but there is a limit to the formation of highly resistive elements in that the occupied surface area on the IC chip is still increased. In view of this situation, a structure is conventionally adopted in which C₁ is externally mounted on the input terminal 10 of IC 4, as shown in FIG. 1. It is relatively easy to use a C₁ that has a large capacitance by using an electrolytic capacitor or the like in the externally mounted structure of coupling capacitor.

However, the above-described conventional circuit has a problem in that the coupling capacitor C₁ is externally mounted on the IC in order to convert the DC level. Therefore, the number of components is increased, assembly time is increased in conjunction with the larger number of components, and the circuit dimensions tend to be enlarged.

### SUMMARY OF THE INVENTION

The present invention provides a semiconductor integrated circuit that can convert a DC level without the use of an externally mounted capacitor.

In the semiconductor integrated circuit of the present invention, a high-pass filter is formed on a shared semiconductor substrate, the filter having a coupling capacitor which is inserted in series in a signal line for transmitting signals and which capacitively couples the output side and input side of the signal pathway, and further having a switched capacitor that functions as an equivalent resistive element between a prescribed reference DC voltage source and a terminal of the coupling capacitor connected to the output side of the signal pathway.

A resistive element having a large resistance value can be equivalently formed over a relatively low occupied surface area on a semiconductor substrate by using a switched capacitor circuit. The capacitance of the coupling capacitor can be reduced in accordance with an increase in the resistance value of the resistive element.

### BRIEF DESCRIPTION OF THE DRAWINGS

FIG. 1 is a schematic view showing the structure of a circuit connection in which a conventional DC cutoff circuit is used;

FIG. 2 is a schematic view showing a circuit structure that includes the IC of the embodiments of the present invention;

FIG. 3 is a circuit diagram showing an example of the basic structure of the switched capacitor circuit that equivalently functions as a resistive element;

FIG. 4 is a circuit diagram showing another example of the basic structure of the switched capacitor circuit that equivalently functions as a resistive element; and

FIG. 5 is a schematic circuit diagram of a high-pass filter formed within the IC.

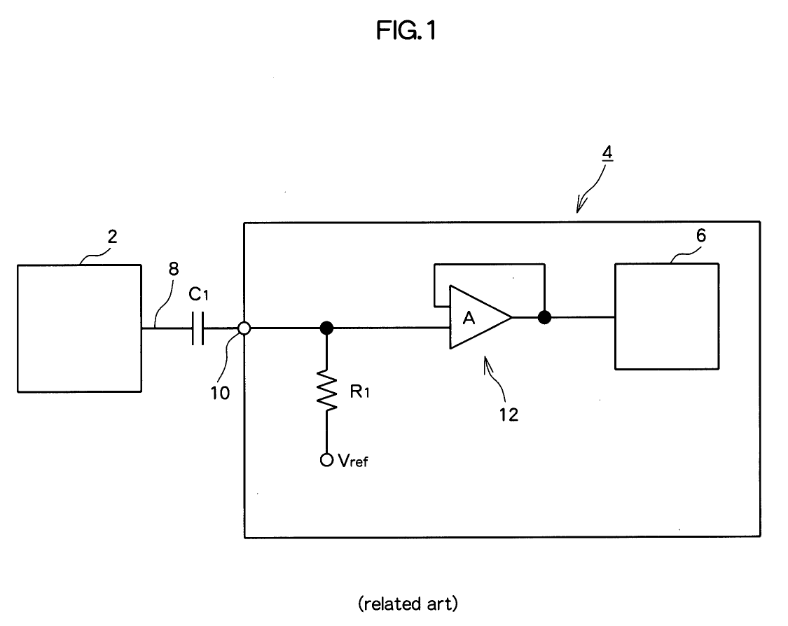

### DESCRIPTION OF THE PREFERRED EMBODIMENTS

Embodiments of the present invention (hereinafter referred to as embodiments) are described below with reference to the diagrams.

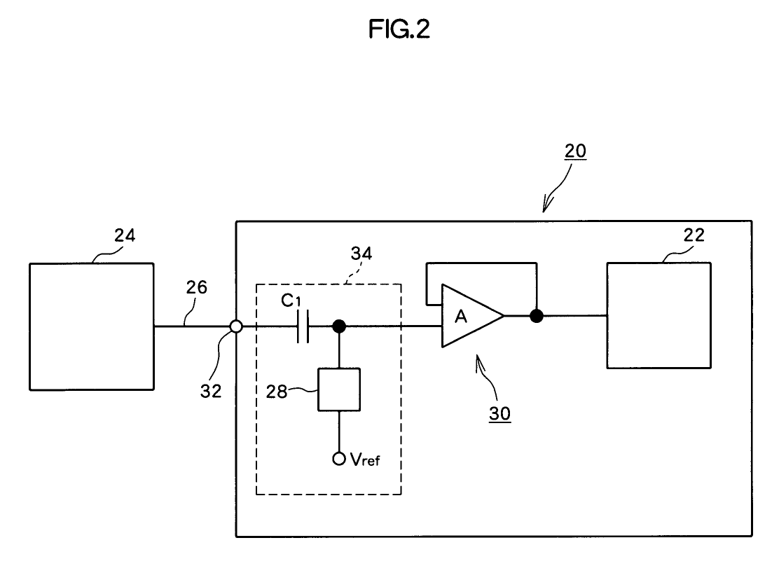

FIG. 2 is a schematic view showing a circuit structure that includes the IC of the embodiments of the present invention. Here, the DC level of the signals in the circuit 22 inside the IC 20 is set so as to be different than the DC level of the signals in the circuit 24 outside the IC 20. For example, the signal transmitted from the circuit 24 to the circuit 22 is in the audio band (20 Hz to 20 kHz). A coupling capacitor C₁ for cutting off the DC of the transmitted signal between the circuits 22 and 24 is inserted in series in the signal line 26 through which the signal is transmitted from the circuit 24 to the circuit 22. This capacitor C₁ has a small and sufficient capacitance as described below, and is therefore integrated and formed together with other circuit elements on the semiconductor chip constituting the IC 20. A switched capacitor circuit 28 and a buffer circuit 30 are furthermore formed on the semiconductor chip.

One of the terminals of the capacitor C₁ is connected to the signal output terminal of the circuit 24 via a connection terminal 32 of the IC 20, for example. The other terminal of the capacitor C₁ is connected to a prescribed reference DC voltage source Vref via the switched capacitor circuit 28, and is also connected to the circuit 22 via the buffer circuit 30.

The switched capacitor circuit 28 functions as an equivalent resistor R_{SC}. The structure of this circuit is described later. The capacitor C₁ and the switched capacitor circuit 28 constituting the equivalent resistor R_{SC} constitute the high-pass filter 34. The high-pass filter 34, as a result of preventing the passage of low-frequency signal components, can set the DC level of the circuit 22 on the output side to a different DC level than the circuit 24 on the input side. The DC level of the output side can be set to Vref, for example.

The buffer circuit 30 is provided with high input impedance using an op-amp A and low output impedance, and converts the impedance between the capacitor C₁ and the circuit 22. The DC level of the circuit 22 is set to Vref via the buffer circuit 30.

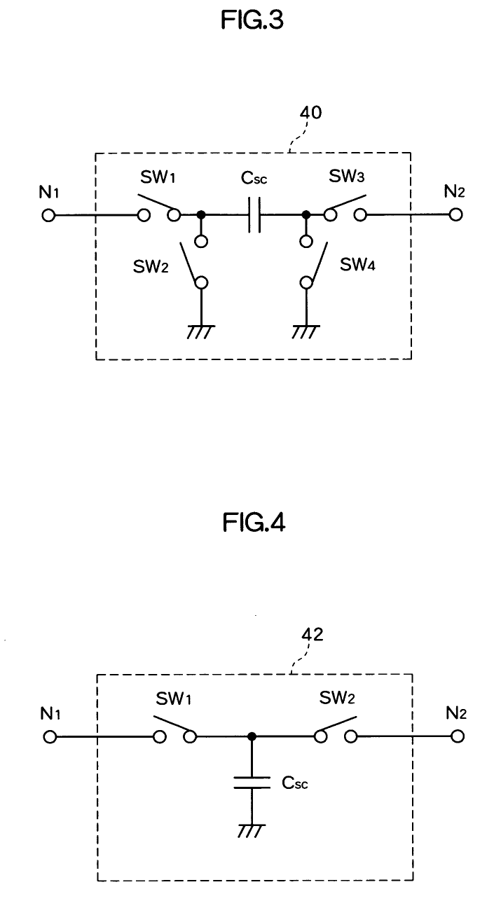

FIG. 3 is a circuit diagram showing an example of the basic structure of the switched capacitor circuit that equivalently functions as a resistive element. This switched capacitor circuit 40 comprises a capacitor C_{SC} and switching elements SW₁ to SW₄. The switch SW₁ is disposed between a terminal N₁ and one terminal of the capacitor C_{SC}, and the terminal of the capacitor C_{SC} can be connected to the ground, which acts as the reference voltage source, by way of the switch SW₂. The switching element SW₃ is disposed between a terminal N₂ and the other terminal of the capacitor C_{SC}, and this other terminal of the capacitor C_{SC} can be connected to the ground, which acts as the reference voltage source, by way of the switching element SW₄. This switched capacitor circuit 40 charges and discharges the capacitor C_{SC} by periodically opening and closing the two switching elements SW₁ and SW₃ and the two switching elements SW₂ and SW₄ in an alternating fashion. Charge is thereby transferred, and pulsed electric current flows between the terminals N₁ and N₂. If the switching frequency f_{SC} is sufficiently high, the average electric current that flows between the terminals N₁ and N₂ will become equivalent to the electric current that passes through the resistance whose resistance value R_{SC} is expressed by the following equation.

R_{SC}=1/(C_{SC}f_{SC}) (2)

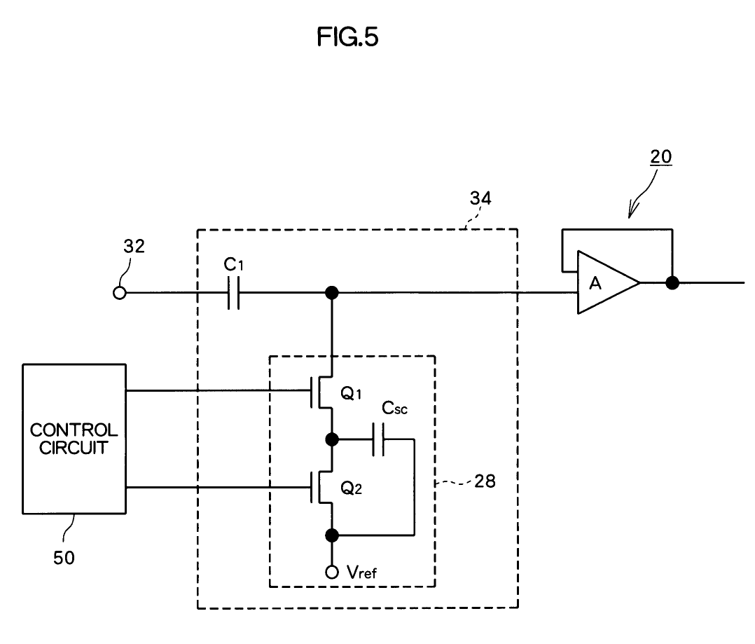

FIG. 4 is a circuit diagram showing another example of the basic structure of the switched capacitor circuit that equivalently functions as a resistive element. This switched capacitor circuit 42 comprises a capacitor C_{SC} and switching elements SW₁ and SW₂. One of the terminals of the capacitor C_{SC} can be connected to the terminal N₁ via the switching element SW₁, and to the terminal N₂ via the switching element SW₂. The other terminal of the capacitor C_{SC} is connected to ground, which acts as the reference voltage source. This switched capacitor circuit 42 charges and discharges the capacitor C_{SC} by periodically opening and closing the two switching elements SW₁ and SW₂ in an alternating fashion. Charge is thereby transferred, and pulsed electric current flows between the terminals N₁ and N₂. The switched capacitor circuit 42 functions as an equivalent resistance expressed in EQ. 2 in the same manner as the switched capacitor circuit 40.

FIG. 5 is a schematic circuit diagram of a high-pass filter 34 formed within the IC 20. The switched capacitor circuit 28 shown in FIG. 5 substantially has the structure shown in FIG. 4. MOS transistors Q₁ and Q₂ that function as switches SW₁ and SW₂ are connected between the capacitor C₁ and the voltage source Vref and are used to control the charging and discharging of the capacitor C_{SC}. The transistors Q₁ and Q₂ each switch gates on and off in accordance with pulses from a control circuit 50, and the transistors control the conduction of electric current between the source and drain. One end of the capacitor C_{SC} is connected to the drain of the transistor Q₁ and to the source of the transistor Q₂, and the other end is connected to the drain of transistor Q₂, which shares a connection with the voltage source Vref. The source of the transistor Q₁ connected to the capacitor C₁ corresponds to the terminal N₁ in FIG. 4, and the drain of the transistor Q₂ connected to the voltage source Vref corresponds to the terminal N₂.

The cutoff frequency f_{C} of the high-pass filter composed of the capacitor C₁ and the equivalent resistance R_{SC} is expressed by the following equation in the same manner as conventional EQ. 1.

f_{C}=1/(2πR_{SC}C₁) (3)

Here, when a signal in the audio band is used as the transmitted signal from the circuit 24 to the circuit 22, the cutoff frequency f_{C} is set to be lower than 20 Hz, which is the lower limit of the audio band. The cutoff frequency f_{C} can be reduced by increasing C₁ or R_{SC}, which is apparent from EQ. 3. It is difficult to form a large capacitance inside an integrated circuit, but an increase in the equivalent resistance R_{SC} composed of a switched capacitor circuit is relatively easy to achieve by reducing f_{SC} or C_{SC}, as is apparent from EQ. 2. In view of this fact, R_{SC} can be increased in this manner to thereby achieve a low cutoff frequency f_{C} while reducing the value of the capacitor C₁ to be small enough to be integrated into the IC 20.

The switching operation of the switched capacitor circuit 28 causes the signal transmitted to the circuit 22 to be sampled and converted from a continuous-time signal into a discrete-time signal. In order to avoid aliasing that accompanies this conversion, the switching frequency f_{SC} must be a sufficiently higher than the audio signal band (20 Hz to 20 kHz), which is the the band of the signal to be transmitted. On the other hand, the cutoff frequency f_{SC} has a limit that corresponds to the operating speed of the transistors Q1 and Q2, to the performance of the pulse-generating control circuit 50, and to other factors.

Considering the above points, the structure of the IC 20 is described below using as an example a case in which C₁ is set to 100 pF as a value that can be incorporated into the IC 20. In this case, when f_{C} is set to 20 Hz, R_{SC} becomes about 80 MΩ on the basis of EQ. 3. C_{SC} and f_{SC}, which give R_{SC}, are determined based on EQ. 2. The range of f_{SC}, e.g., about 100 kHz to 1 MHz, satisfies the condition related to the upper and lower limits of the cutoff frequency f_{SC}. In view of this fact, C_{SC} is 125 fF when f_{SC} is set to 100 kHz, C_{SC} is 25 fF when f_{SC} is set to 500 kHz, and C_{SC} is 12.5 fF when f_{SC} is set to 1 MHz. In other words, in the above-described range of f_{SC}, C_{SC} is a small capacitance on the order of several tens to several hundred fF and can be formed inside the IC 20. The fact that C_{SC} is sufficient at such a very small capacitance shows that a C_{SC} can be implemented with the parasitic capacitance of the wiring or the source and drain diffusion layer of the transistors Q₁ and Q₂, which correspond to the connection points of the capacitor. In other words, the C_{SC} pattern does not need to be formed in the regular manner on the semiconductor substrate, and the surface area occupied by the switched capacitor circuit 28 on the IC 20 is reduced. In this respect, the DC level conversion circuit is suitable for use in the IC 20. Configuring the C_{SC} using parasitic capacitance may lead to difficulty in controlling variability. However, this aspect will not present an obstacle to forming C_{SC} by using parasitic capacitance when f_{C} needs only to be at or below a prescribed value, as in the present circuit.

R_{C} is very high at a low f_{C}, as described above. A large resistance thus presents difficulties in that the occupied surface area is increased when the resistance is formed on the semiconductor chip using polysilicon or the like. However, the occupied surface area can be reduced by using a method in which an equivalent resistance is formed using a switched capacitor in the manner described above.

In order to assure the operation of the high-pass filter 34 in the structure described above, the impedance of the output terminal must be set to a high level. An example of a structure provided with a buffer circuit 30 is shown in order to illustrate this fact. However, other structures can also be used if the structures are such that the output impedance of the high-pass filter 34 is set to a high level. The control circuit 50 for controlling the switching of the switched capacitor circuit 28 may be formed on the chip of the IC 20. The control circuit may also be formed as an external circuit or may be formed so that a control signal is applied from the terminal of the IC 20 to the transistors Q₁ and Q₂ or other such switching elements.

In the semiconductor integrated circuit of the present invention as described above, a high-pass filter is formed on a shared semiconductor substrate, the filter having a coupling capacitor which is inserted in series in a signal line for transmitting signals and which capacitively couples the output side and input side of the signal pathway, and further having a switched capacitor that functions as an equivalent resistive element between a prescribed reference DC voltage source and a terminal of the coupling capacitor connected to the output side of the signal pathway.

A resistive element having a large resistance value can be equivalently formed over a relatively low occupied surface area on a semiconductor substrate by using a switched capacitor circuit. The capacitance of the coupling capacitor can be reduced in accordance with an increase in the resistance value of the resistive element.

The semiconductor integrated circuit of the present invention described above is advantageous in cases in which the cutoff frequency of the high-pass filter is set to be lower than the lower limit of the audible frequency band. Specifically, the present invention is also effective for converting the DC level of signals in the audible frequency band, which is a relatively low frequency [band] among transmitted signals. From this standpoint, when the cutoff frequency of the high-pass filter must be set to a low frequency, the capacitance of the coupling capacitor must be increased in a conventional structure, making the coupling capacitance difficult to incorporate into an integrated circuit in particular.

The switched capacitor circuit in the semiconductor integrated circuit of the present invention, like the switched capacitor circuit 28, has a first switching element in which one end is connected to the terminal of the coupling capacitor connected to the output side of the signal pathway; a second switching element connected between the reference DC voltage source and the other end of the first switching element; and a buffer capacitor which is disposed in parallel with the second switch between the reference DC voltage source and the other end of the first switching element and which is charged and discharged in accordance with the on/off operation of the first switching element and the second switching element. Switching elements are ordinarily disposed at the two ends of the capacitor when the resistive element is equivalently configured in a switched capacitor circuit. In the above structure, however, switching elements are disposed at only one end of the capacitor, thereby simplifying the circuit.

The buffer capacitor in the semiconductor integrated circuit of the present invention described above is composed of a parasitic capacitance of the connection part between the first switching element and the second switching element.

In accordance with the semiconductor integrated circuit of the present invention described above, a coupling capacitor can be incorporated into a semiconductor integrated circuit, the number of components and assembly time can be reduced, and the circuit size can be reduced as well.

What is claimed is:

1. A semiconductor integrated circuit in which a high-pass filter is formed on a shared semiconductor substrate, said high-pass filter comprising:
a coupling capacitor which is inserted in series in a signal pathway for transmitting signals and which capacitively couples output side and input side of said signal pathway; and
a switched capacitor circuit that functions as an equivalent resistive element between a prescribed reference DC voltage source and a terminal of said coupling capacitor connected to said output side of said signal pathway.

2. The semiconductor integrated circuit according to claim 1, wherein a cutoff frequency of said high-pass filter is set to be lower than the lower limit of an audible frequency band.

3. The semiconductor integrated circuit according to claim 1, wherein said switched capacitor circuit comprises:
a first switching element in which one end is connected to said terminal of said coupling capacitor connected to said output side of said signal pathway;
a second switching element connected between said reference DC voltage source and the other end of said first switching element; and
a buffer capacitor which is disposed in parallel with said second switching element between said reference DC voltage source and the other end of said first switching element and which is charged and discharged in accordance with on/off operation of said first switching element and said second switching element.

4. The semiconductor integrated circuit according to claim 3, wherein said buffer capacitor is composed of a parasitic capacitance of a connection part between said first switching element and said second switching element.
